(19) United States
(12) Patent Application Publication
(10) Pub. No.: US 2026/0082964 A1
(43) Pub. Date: Mar. 19, 2026

(54) SEMICONDUCTOR DEVICE

(71) Applicant: FUJI ELECTRIC CO., LTD., Kawasaki-shi (JP)

(72) Inventor: Hayato NAKANO, Kofu-city (JP)

(73) Assignee: FUJI ELECTRIC CO., LTD., Kawasaki-shi (JP)

(21) Appl. No.: 19/307,760

(22) Filed: Aug. 22, 2025

(30) Foreign Application Priority Data
Sep. 17, 2024 (JP) 2024-160386

(51) Int. Cl. H01L 23/498; H01L 23/00; H01L 23/29; H01L 23/31; H01L 23/373; H01L 25/07; H10D 80/20

(52) U.S. Cl. CPC H10W 70/658; H10D 80/215; H10D 80/251; H10W 40/255; H10W 74/114; H10W 74/473; H10W 90/00; H10W 90/734

(57) ABSTRACT

A semiconductor device, including: a semiconductor chip; an insulated circuit substrate that has: a metal plate including a ground region on an upper surface thereof, an insulating layer disposed on the upper surface of the metal plate with the ground region exposed therefrom, and a conductive circuit pattern plate on which the semiconductor chip is mounted; a ground wiring member conductively connected to the ground region of the metal plate, the ground wiring member being conductive and including an upper end portion located above the insulated circuit substrate; and a sealing member sealing the semiconductor chip, the insulated circuit substrate and the ground wiring member, the sealing member having a sealing upper surface and including an opening formed therein to expose therethrough the upper end portion of the ground wiring member above the insulated circuit substrate.

### CROSS-REFERENCE TO RELATED APPLICATION

This application is based upon and claims the benefit of priority of the prior Japanese Patent Application No. 2024-160386, filed on Sep. 17, 2024, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a semiconductor module and a cooling module on which the semiconductor module is disposed. The semiconductor module includes an insulated circuit substrate having a plurality of conductive circuit pattern plates formed on the upper surface thereof, and semiconductor chips disposed on the conductive circuit pattern plates. Such a semiconductor module includes a terminal that is conductively connected to a conductive circuit pattern plate and extends vertically upward from the conductive circuit pattern plate (see, for example, Japanese Laid-open Patent Publication No. 2021-125545, Japanese Laid-open Patent Publication No. 2011-253862, Japanese Laid-open Patent Publication No. 09-321216, Japanese Laid-open Patent Publication No. 2022-160270, and Japanese National Publication of International Patent Application No. 2020-526930). In addition, in the semiconductor module, a conductive member is connected to a fastening portion of a metal plate formed on the lower surface of the insulated circuit substrate (for example, see Japanese Laid-open Patent Publication No. 2022-048552 and Japanese Laid-open Patent Publication No. 2020-087966).

### SUMMARY OF THE INVENTION

According to one aspect, there is provided a semiconductor device, including: a semiconductor chip; an insulated circuit substrate, including: a metal plate including a ground region on an upper surface thereof, an insulating layer disposed on the upper surface of the metal plate, with the ground region exposed therefrom, and a conductive circuit pattern plate on which the semiconductor chip is mounted; a ground wiring member conductively connected to the ground region of the metal plate, the ground wiring member being conductive and including an upper end portion located above the insulated circuit substrate; and a sealing member sealing the semiconductor chip, the insulated circuit substrate, and the ground wiring member, the sealing member having a sealing upper surface and including an opening formed therein to expose therethrough the upper end portion of the ground wiring member above the insulated circuit substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side view of a power conversion system according to a first embodiment;

FIG. 2 is a plan view of a semiconductor device according to the first embodiment;

FIG. 3 is a plan view of the semiconductor device (excluding a sealing member) according to the first embodiment;

FIG. 4 is a plan view of an insulated circuit substrate according to the first embodiment;

FIG. 5 is a first sectional view of the semiconductor device according to the first embodiment;

FIG. 6 is a second sectional view of the semiconductor device (excluding the sealing member) according to the first embodiment;

FIG. 7 is a plan view of a semiconductor device according to a second embodiment;

FIG. 8 is a plan view of the semiconductor device (excluding a sealing member) according to the second embodiment;

FIG. 9 is a plan view of an insulated circuit substrate according to the second embodiment;

FIG. 10 is a first sectional view of the semiconductor device according to the second embodiment; and

FIG. 11 is a second sectional view of the semiconductor device (excluding the sealing member) according to the second embodiment.

### DETAILED DESCRIPTION OF THE INVENTION

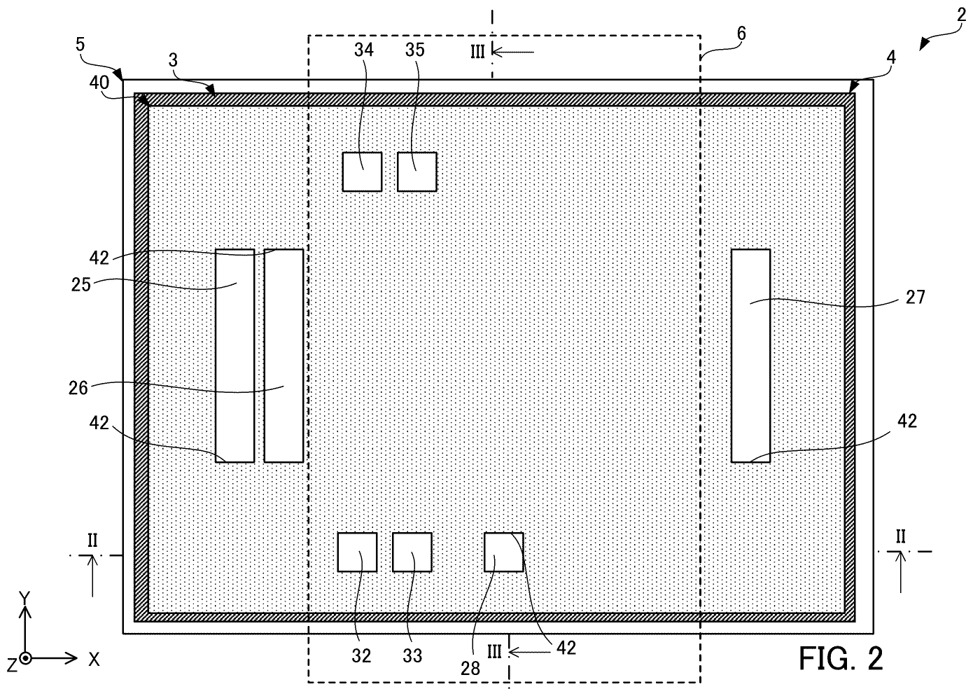

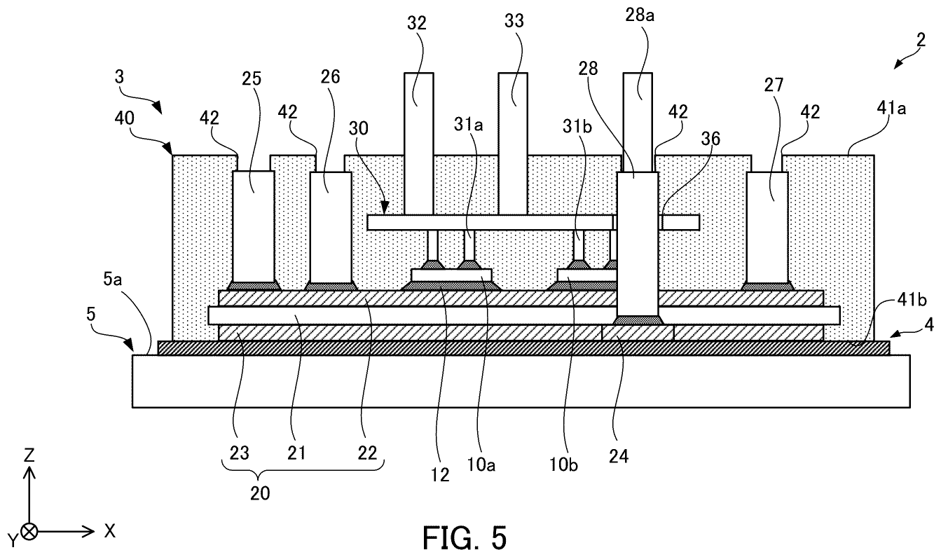

Hereinafter, embodiments will be described with reference to the drawings. In the following description, a “front surface” and an “upper surface” refer to an X-Y plane facing upward (+Z direction) in a semiconductor device 2 of FIGS. 2 and 5. Similarly, “above” indicates, for example, an upward direction (+Z direction) in the semiconductor device 2 of FIG. 5. A “rear surface” and a “lower surface” refer to, for example, an X-Y plane facing downward (−Z direction) in the semiconductor device 2 of FIG. 5. Similarly, “below” indicates, for example, a downward direction (−Z direction) in the semiconductor device 2 of FIG. 5. The same directions are used in the other drawings as appropriate. The terms “front surface”, “upper surface”, “above”, “rear surface”, “lower surface”, “below”, and “side surface” are merely expressions for convenience to describe relative positional relationship, and do not limit the technical idea of the present embodiments. For example, “above” and “below” are not necessarily related to the vertical direction with respect to the ground. That is, the “above” and “below” directions are not limited to the gravity direction. In addition, in the following description, a “main component” refers to a component contained at 80 vol % or more. Further, the expression “being substantially the same” permits a variation of ±10%. In addition, the expressions “being vertical” and “being parallel” permit a variation of ±10°.

### FIRST EMBODIMENT

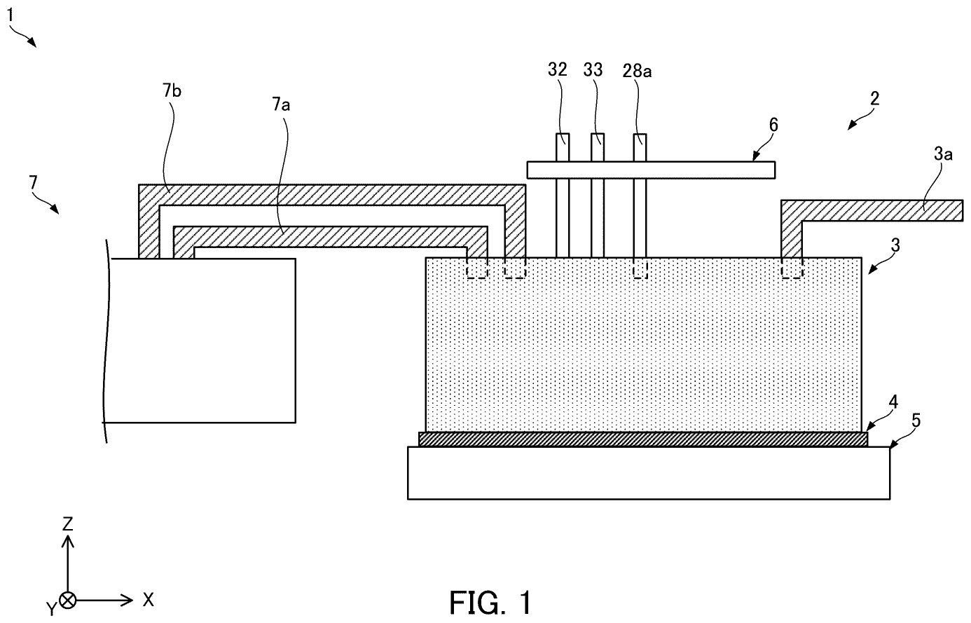

A power conversion system 1 according to a first embodiment will be described with reference to FIG. 1. FIG. 1 is a side view of the power conversion system according to the first embodiment. The power conversion system 1 includes a semiconductor device 2, a first printed board 6, and a capacitor 7.

The semiconductor device 2 includes a semiconductor module 3 and a cooling module 5 on which the semiconductor module 3 is disposed via a bonding member 4. The semiconductor module 3 includes semiconductor chips having a switching function, and functions as an inverter. The semiconductor module 3 includes, for example, three main terminals, two control terminals, and two sense terminals. FIG. 1 illustrates a first control terminal 32 and a first sense terminal 33. In addition, the semiconductor module 3 includes a ground connection terminal 28a.

The first printed board 6 is provided to two control terminals, two sense terminals, and the ground connection terminal 28a, which are included in the semiconductor module 3. A control current applied from the outside is input to the two control terminals via the first printed board 6. An output current output from the semiconductor device 2 flows through the two sense terminals, and is then detected by an external device via the first printed board 6. The first printed board 6 is also attached to the ground connection terminal 28a, as well as the two control terminals and the two sense terminals, so that the first printed board 6 is stably provided to the semiconductor module 3.

The capacitor 7 includes a capacitor element having a first electrode and a second electrode (not illustrated), and a case that houses the capacitor element. The capacitor 7 includes bus bars 7a and 7b connected to the first electrode and the second electrode, respectively. One end of each of the bus bars 7a and 7b is connected to the corresponding one of the first electrode and the second electrode within the case, from the upper surface of the capacitor 7. The other ends of the bus bars 7a and 7b are electrically connected to two main terminals included in the semiconductor module 3, respectively. A bus bar 3a is electrically connected to the remaining main terminal included in the semiconductor device 2.

The bus bars 3a, 7a, and 7b are made of metal having excellent thermal conductivity. Examples of such a material include copper, aluminum, and an alloy containing at least one of them. Here, copper is contained. In order to improve corrosion resistance, the surfaces of the bus bars 3a, 7a, and 7b may be plated. The plating material in this case contains nickel. Examples of such a plating material include nickel, a nickel-phosphorus alloy, and a nickel-boron alloy.

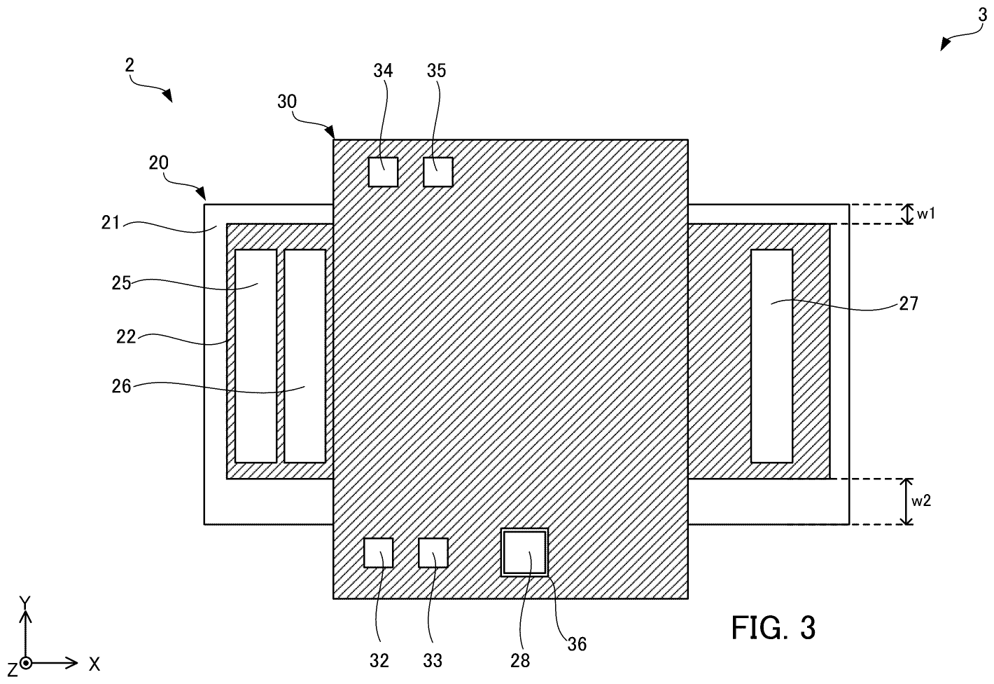

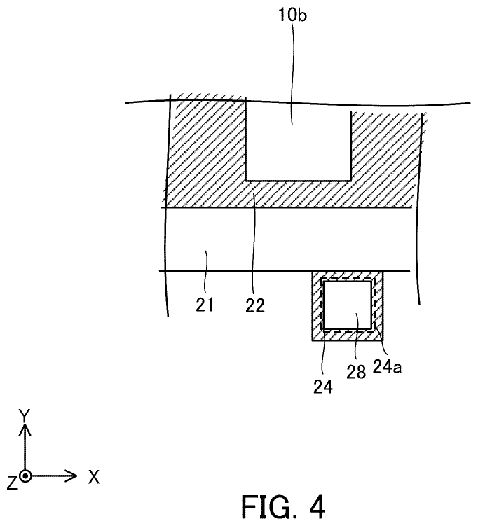

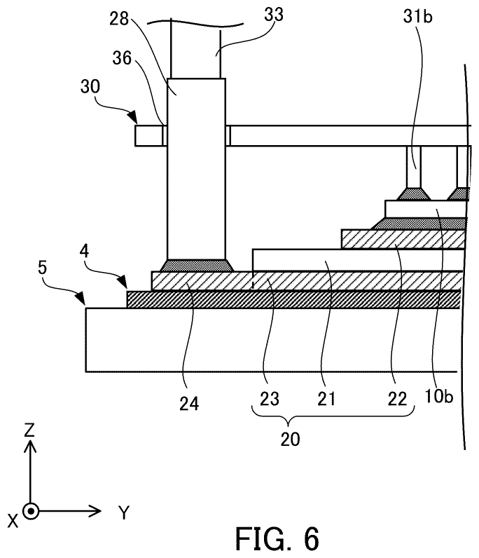

Next, the semiconductor device 2 will be described in detail with reference to FIGS. 2 to 6. FIG. 2 is a plan view of the semiconductor device according to the first embodiment. FIG. 3 is a plan view of the semiconductor device (excluding a sealing member) according to the first embodiment. FIG. 4 is a plan view of an insulated circuit substrate according to the first embodiment. FIG. 5 is a first sectional view of the semiconductor device according to the first embodiment. FIG. 6 is a second sectional view of the semiconductor device (excluding the sealing member) according to the first embodiment.

More specifically, FIG. 3 is a plan view of the semiconductor module 3 (semiconductor device 2) with a sealing member 40 removed from FIG. 2. FIG. 4 is an enlarged view illustrating a ground region 24a and the periphery of the ground region 24a in an insulated circuit substrate 20 of FIG. 3. FIG. 5 is a sectional view taken along the dot-dashed line II-II of FIG. 2. FIG. 6 is a sectional view taken along the dot-dashed line III-III of FIG. 2. Note that, in FIG. 6, the sealing member 40 is not illustrated.

As described above, the semiconductor device 2 includes the semiconductor module 3, the cooling module 5 on which the semiconductor module 3 is disposed via the bonding member 4, and the first printed board 6 attached to the semiconductor module 3. The arrangement position of the first printed board 6 with respect to the semiconductor module 3 is indicated by a broken line in FIG. 2, and is not indicated in other drawings. Note that the semiconductor module 3 may include other needed components in addition to these components.

The semiconductor module 3 includes semiconductor chips 10a and 10b, the insulated circuit substrate 20, a second printed board 30, a first main terminal 25, a second main terminal 26, a third main terminal 27, and a ground terminal 28, and also includes the sealing member 40 that seals these components.

The semiconductor chips 10a and 10b may be power metal-oxide-semiconductor field-effect transistors (MOSFETs) made of silicon carbide as a main component. In a power MOSFET, the body diode may function as a free-wheeling diode (FWD). The semiconductor chips 10a and 10b of this type each have, for example, an input electrode (drain electrode) as a main electrode on the rear surface thereof, and an output electrode (source electrode) as a main electrode and a control electrode (gate electrode) on the front surface thereof. The control electrode may be provided at the center of one side portion of the front surface of each of the semiconductor chips 10a and 10b or at a position shifted from the center along the side portion.

Alternatively, the semiconductor chips 10a and 10b may each include a switching element made of silicon as a main component. The switching element is, for example, a reverse-conducting insulated gate bipolar transistor (RC-IGBT). The RC-IGBT is a semiconductor element in which an IGBT and an FWD are configured in inverse-parallel in one chip.

The semiconductor chips 10a and 10b of this type each have an input electrode (collector electrode) as a main electrode on the rear surface thereof, and an output electrode (emitter electrode) as a main electrode and a control electrode (gate electrode) on the front surface thereof. As in the case of the power MOSFET, the control electrode may be provided at the center of one side portion of the front surface of each of the semiconductor chips 10a and 10b or at a position shifted from the center along the side portion.

Further, for example, the semiconductor chips 10a and 10b may be semiconductor chips that are made of silicon as a main component and may be a set of a switching element and a diode element. Specifically, the semiconductor chip 10a may be a switching element, and the semiconductor chip 10b may be a diode element. The switching element is, for example, a power MOSFET or an IGBT. A semiconductor chip including a switching element has, for example, an input electrode (a drain electrode in a power MOSFET and a collector electrode in an IGBT) as a main electrode on the rear surface thereof, and a gate electrode as a control electrode and an output electrode (a source electrode in a power MOSFET and an emitter electrode in an IGBT) as a main electrode on the front surface thereof. As the diode element, for example, a Schottky barrier diode (SBD) or a P-intrinsic-N (PiN) diode is used as the FWD. A semiconductor chip including a diode element has an output electrode (cathode electrode) as a main electrode on the rear surface thereof and an input electrode (anode electrode) as a main electrode on the front surface thereof.

The semiconductor chips 10a and 10b may be bonded to a conductive circuit pattern plate 22, which will be described later, by solder 12. The solder 12 is made of a solder component. The solder component is a substance constituting the solder 12 and includes a lead-free solder containing a predetermined alloy as a main component. The predetermined alloy contains tin. Such an alloy is, for example, at least one of an alloy of tin-silver, an alloy of tin-silver-copper, an alloy of tin-zinc-bismuth, an alloy of tin-copper, an alloy of tin-silver-indium-bismuth, and an alloy of tin-antimony. Furthermore, such a solder component may include an additive. Examples of the additive include nickel, germanium, cobalt, and silicon. Therefore, for example, the solder component includes tin, and at least one of silver, zinc, copper, bismuth, indium, and antimony. In addition, for example, the solder component may further include at least one of nickel, germanium, cobalt, and silicon. A sintered body may be used instead of the solder 12. In the case of using a sintered body for the bonding, the sintered material is, for example, silver, iron, copper, aluminum, titanium, nickel, tungsten, or molybdenum in powder form.

The insulated circuit substrate 20 includes an insulating layer 21, the conductive circuit pattern plate 22, and a metal plate 23. Further, the metal plate 23 is provided with a ground metal plate 24. The insulating layer 21 and the metal plate 23 have a rectangular shape in plan view. The corners of the insulating layer 21 and the metal plate 23 may be R-chamfered or C-chamfered. In plan view, the size of the metal plate 23 is smaller than that of the insulating layer 21, and the metal plate 23 is formed inside the insulating layer 21.

Examples of the insulating layer 21 include a ceramic substrate. The ceramic substrate is made of a ceramic material having high thermal conductivity. The ceramic material is made of, for example, a material containing aluminum oxide, aluminum nitride, or silicon nitride as a main component. The insulating layer 21 has a rectangular shape in plan view. Examples of the insulated circuit substrate 20 including the insulating layer 21 having such a configuration include a direct copper bonding (DCB) substrate and an active metal brazed (AMB) substrate.

Alternatively, the insulating layer 21 may be made of resin. The resin may be a material having low thermal resistance and high insulating property. Examples of such a resin include a thermosetting resin. The thermosetting resin may further contain a filler. The thermal resistance of the insulating layer 21 may be further reduced by controlling the material and content of the filler in the insulating layer 21.

Examples of such a thermosetting resin include at least one of epoxy resin, cyanate resin, polyimide resin, benzoxazine resin, unsaturated polyester resin, phenol resin, melamine resin, silicone resin, and maleimide resin. The filler is made of at least one of an oxide and a nitride. Examples of the oxide include silicon oxide and aluminum oxide. Examples of the nitride include silicon nitride, aluminum nitride, and boron nitride. Further, a hexagonal boron nitride may be used as the filler.

The thickness of the insulating layer 21 depends on the rated voltage of the semiconductor module 3. That is, as the rated voltage of the semiconductor module 3 is higher, the insulating layer 21 needs to be thicker. On the other hand, the insulating layer 21 needs to be as thin as possible, in order to reduce the thermal resistance.

The semiconductor chips 10a and 10b, the first main terminal 25 (main terminal wiring member), the second main terminal 26 (main terminal wiring member), and the third main terminal 27 (main terminal wiring member) are disposed on the conductive circuit pattern plate 22. The conductive circuit pattern plate 22 is formed over the entire surface of the insulating layer 21 except the edge portion thereof. Preferably, in plan view, the edge of the conductive circuit pattern plate 22 facing the outer periphery of the insulating layer 21 is aligned with the outer peripheral edge of the metal plate 23. Therefore, the insulated circuit substrate 20 maintains the stress balance between the conductive circuit pattern plate 22 provided on the front surface of the insulating layer 21 and the metal plate 23 provided on the rear surface of the insulating layer 21. This further reduces the likelihood of damage such as excessive warpage and cracking of the insulating layer 21. In the first embodiment, one conductive circuit pattern plate 22 is illustrated for convenience. Actually, the quantity, shapes, and sizes of conductive circuit pattern plates 22 are selected to achieve a desired circuit, and the conductive circuit pattern plates 22 are formed on the insulating layer 21.

The metal plate 23 is made of metal having excellent thermal conductivity. Examples of such a material include copper, aluminum, and an alloy containing at least one of them. Here, copper is contained. In order to improve corrosion resistance, the surface of the metal plate 23 may be plated. The plating material in this case contains nickel. Examples of such a plating material include nickel, a nickel-phosphorus alloy, and a nickel-boron alloy.

The ground metal plate 24 has a ground region 24a, which has a ground terminal 28 to be described later disposed on the upper surface thereof. This ground metal plate 24 may be integrally formed at any one of the four sides of the metal plate 23 in plan view. As will be described later, the ground terminal 28 is disposed at the other end side opposite to the first main terminal 25 and the second main terminal 26 in the insulated circuit substrate 20 in plan view. More specifically, the ground terminal 28 is disposed at a side closer to the third main terminal 27 than are the first main terminal 25 and the second main terminal 26. Therefore, the ground metal plate 24 needs to be formed on the metal plate 23 so that the ground terminal 28 is arranged as described above. The ground metal plate 24 may have a similar thickness to the metal plate 23 and extends outwardly perpendicular to the side of the metal plate 23 at which the ground metal plate 24 is formed. For example, in the first embodiment, the ground metal plate 24 is integrally formed on the −Y-direction long side of the metal plate 23 and extends in the −Y direction with respect to the long side in plan view. The ground metal plate 24 has a size capable of securing the ground region 24a where the ground terminal 28 described later is disposed on the upper surface thereof, and may have a rectangular shape, a circular shape, a semicircular shape, or a polygonal shape in plan view. The ground metal plate 24 of the first embodiment has a rectangular shape in plan view. That is, with respect to the metal plate 23, a portion (ground metal plate 24) including the ground region 24a projects from one side (side portion) of the metal plate 23 perpendicularly (outward) to the one side.

For example, as illustrated in FIG. 3, the width of the gap between the side of the insulating layer 21 on which the ground metal plate 24 is formed and the side of the conductive circuit pattern plate 22 facing this side is denoted as a width w2. In addition, the width of the gap between the side of the insulating layer 21 opposite to the ground metal plate 24 and the side of the conductive circuit pattern plate 22 facing this side is denoted as a width w1. In this case, the width w2 needs to be greater than or equal to, for example, (width w1×2) plus (the thickness of the insulating layer 21). By this setting, the creepage distance between the ground metal plate 24 and the conductive circuit pattern plate 22 is secured.

The first main terminal 25, the second main terminal 26, the third main terminal 27, and the ground terminal 28 are made of a material having excellent electrical conductivity. Examples of such a material include copper, aluminum, and an alloy containing at least one of them. The first main terminal 25, the second main terminal 26, the third main terminal 27, and the ground terminal 28 may be plated with a material having excellent corrosion resistance. Examples of such a material include nickel, a nickel-phosphorus alloy, and a nickel-boron alloy.

The first main terminal 25, the second main terminal 26, the third main terminal 27, and the ground terminal 28 may have a columnar shape. The first main terminal 25, the second main terminal 26, and the third main terminal 27 have a prismatic shape that is rectangular (flat plate shape) in plan view. The ground terminal 28 may have a prismatic shape or a cylindrical shape. Here, the ground terminal 28 is illustrated as having a prismatic shape. Both ends of each of the first main terminal 25, the second main terminal 26, the third main terminal 27, and the ground terminal 28 are flat.

The first main terminal 25 serves as a positive terminal of the semiconductor module 3. The second main terminal 26 serves as a negative terminal of the semiconductor module 3. The third main terminal 27 serves as an output terminal of the semiconductor module 3. The ground terminal 28 is an example of a ground wiring member, is electrically connected to the metal plate 23 via the ground metal plate 24, and functions as the ground of the semiconductor module 3.

The lower end portions of the first main terminal 25, the second main terminal 26, and the third main terminal 27 are joined to the conductive circuit pattern plate 22 by the solder 12, and extend vertically upward with respect to the conductive circuit pattern plate 22. The first main terminal 25 and the second main terminal 26 are provided side by side at one short side (−X direction) of the insulated circuit substrate 20 in plan view. The third main terminal 27 is provided at the other short side (+X direction) of the insulated circuit substrate 20 in plan view.

The lower end portion of the ground terminal 28 is bonded to the ground region 24a of the ground metal plate 24 via the solder 12. The upper end portion (first upper end portion) of the ground terminal 28 extends vertically upward with respect to the ground metal plate 24 (insulated circuit substrate 20) and is located above the insulated circuit substrate 20 (and the second printed board 30). The ground terminal 28 is disposed at the other end side opposite to the first main terminal 25 and the second main terminal 26 in the insulated circuit substrate 20 in plan view.

The second printed board 30 includes an insulating layer and a plurality of upper circuit pattern layers formed on the front surface of the insulating layer. The second printed board 30 may include a plurality of lower circuit pattern layers on the rear surface of the insulating layer. The second printed board 30 includes the first control terminal 32, the first sense terminal 33, a second control terminal 34, and a second sense terminal 35 on the upper surface thereof. The second printed board 30 includes implant pins 31a and 31b on the lower surface thereof. Further, the second printed board 30 is formed with an opening 36 through which the ground terminal 28 described later is inserted.

The second printed board 30 is placed above and overlaps the upper surface of the insulated circuit substrate 20 in plan view. For example, as illustrated in FIG. 3, the second printed board 30 is disposed so as to lie in the ±Y direction between the second main terminal 26 and the third main terminal 27 provided on the insulated circuit substrate 20 in plan view.

On the second printed board 30, the first control terminal 32 and the first sense terminal 33, and the second control terminal 34 and the second sense terminal 35 are formed so as to extend vertically upward with respect to the upper surface of the second printed board 30, and are located at the ±Y-direction end sides of the second printed board 30 and outside their corresponding end sides of the insulated circuit substrate 20.

When the second printed board 30 is disposed above the insulated circuit substrate 20 as described above, the implant pins 31a and 31b extend vertically downward with respect to the lower surface of the second printed board 30 and are bonded to the control electrodes and the output electrodes of the semiconductor chips 10a and 10b via the solder 12.

Further, in the second printed board 30, the opening 36 is formed at a position facing the ground region 24a of the ground metal plate 24. The opening area and the shape of the opening 36 may be set so as to allow the ground terminal 28 to be inserted therein without touching the opening 36.

The first control terminal 32, the first sense terminal 33, the second control terminal 34, the second sense terminal 35, and the implant pins 31a and 31b are made of a material having excellent electrical conductivity. Examples of such a material include copper, aluminum, and an alloy containing at least one of them. The first control terminal 32, the first sense terminal 33, the second control terminal 34, the second sense terminal 35, and the implant pins 31a and 31b may be plated with a material having excellent corrosion resistance. Examples of such a material include nickel, a nickel-phosphorus alloy, and a nickel-boron alloy.

The first control terminal 32, the first sense terminal 33, the second control terminal 34, and the second sense terminal 35 are each electrically connected to a predetermined upper circuit pattern layer and a predetermined lower circuit pattern layer in the second printed board 30.

The implant pins 31a and 31b are also each electrically connected to a predetermined upper circuit pattern layer and a predetermined lower circuit pattern layer in the second printed board 30. The implant pins 31a and 31b are electrically connected, as appropriate, to the first control terminal 32, the first sense terminal 33, the second control terminal 34, and the second sense terminal 35 via the upper circuit pattern layer and the lower circuit pattern layer.

The sealing member 40 entirely seals the insulated circuit substrate 20, the semiconductor chips 10a and 10b, the second printed board 30, the first main terminal 25, the second main terminal 26, and the third main terminal 27, and has a cubic shape including a sealing upper surface 41a and a sealing lower surface 41b. The sealing upper surface 41a and the sealing lower surface 41b may be located opposite to each other and have the same shape and the same size in plan view. The lower surfaces of the metal plate 23 and the ground metal plate 24 of the insulated circuit substrate 20 are exposed from the sealing lower surface 41b.

Openings 42 are formed in the sealing upper surface 41a of the sealing member 40. The flat surfaces (first flat surfaces) of the upper end portions (first upper end portions) of the first main terminal 25, the second main terminal 26, the third main terminal 27, and the ground terminal 28 are exposed in the openings 42. The bus bars 7a and 7b of the capacitor 7 are respectively bonded to the flat surfaces of the upper end portions of the first main terminal 25 and the second main terminal 26 through the openings 42. The bus bar 3a is bonded to the flat surface of the upper end portion of the third main terminal 27 through the opening 42. Further, the ground connection terminal 28a is bonded to the flat surface of the upper end portion of the ground terminal 28 through the opening 42. The bonding to the first main terminal 25, the second main terminal 26, the third main terminal 27, and the ground terminal 28 may be performed using, for example, the above-described solder.

The upper end portions of the first control terminal 32, the first sense terminal 33, the second control terminal 34, and the second sense terminal 35 provided on the second printed board 30 project vertically upward from the sealing upper surface 41a of the sealing member 40 and are exposed. As illustrated in FIGS. 1 and 5 (here, the first control terminal 32 and the first sense terminal 33 are illustrated), the upper end portions of the first control terminal 32, the first sense terminal 33, the second control terminal 34, and the second sense terminal 35 are flush with the upper end portion of the ground connection terminal 28a.

The sealing member 40 may be a thermosetting resin containing a filler. Examples of the thermosetting resin include an epoxy resin, a phenol resin, a maleimide resin, and a polyester resin. The filler may contain, as a main component, an insulating ceramic material having high thermal conductivity. Examples of such a filler include silicon oxide, aluminum oxide, boron nitride, and aluminum nitride.

The cooling module 5 has, on its upper surface, a mounting surface 5a on which the lower surface (sealing lower surface 41b) of the semiconductor module 3 is placed. The mounting surface 5a is wider than the sealing lower surface 41b, which serves as the rear surface of the semiconductor module 3, and is substantially flat. The cooling module 5 may be, for example, a heat dissipation base including heat dissipation fins or a cooling device in which a refrigerant circulates. At least a portion of the cooling module 5 including the mounting surface 5a, on which the semiconductor module 3 is placed, is made of metal having excellent thermal conductivity. Examples of such a material include copper, aluminum, and an alloy containing at least one of them. Here, copper is contained. In addition, in order to improve corrosion resistance, a plating process may be performed on the mounting surface 5a of the cooling module 5. The plating material in this case contains nickel. Examples of such a plating material include nickel, a nickel-phosphorus alloy, and a nickel-boron alloy.

The bonding member 4 is provided between the sealing lower surface 41b of the semiconductor module 3 and the mounting surface 5a of the cooling module 5. That is, in plan view seen in the −Z direction, the shape and size of the bonding member 4 substantially match the shape and size of the lower surface of the semiconductor module 3. That is, the bonding member 4 is in contact with the sealing lower surface 41b of the semiconductor module 3 and is in contact with the mounting surface 5a of the cooling module 5.

This bonding member 4 may be a thermally conductive adhesive, and may be made of a material having thermal conductivity, insulating property, and adhesive property. A material that exhibits a predetermined thermal conductivity may be selected. The bonding member 4 may contain, for example, resin as a main component and a filler. The resin may be, for example, epoxy-based resin. The filler contains, for example, a ceramic material or metal as a main component. The ceramic material has high thermal conductivity, and examples thereof include silicon oxide, aluminum oxide, boron nitride, and aluminum nitride. In the case where the filler is a ceramic material, the bonding member 4 containing such a filler is able to exhibit thermal conductivity in addition to adhesiveness. The metal has high thermal conductivity and electrical conductivity, and is, for example, silver, copper, gold, nickel, chromium, aluminum, or an alloy containing at least one of them. In the case where the filler is metal, the bonding member 4 containing such a filler exhibits thermal conductivity in addition to adhesiveness, and also has electrical conductivity. Since the bonding member 4 has electrical conductivity, the metal plate 23 and the ground metal plate 24 exposed from the sealing lower surface 41b of the semiconductor module 3, and the cooling module 5 have the same potential, which makes it possible to prevent the occurrence of discharge between the semiconductor module 3 and the cooling module 5. The outer corners of the bonding member 4 may be R-chamfered. By doing so, stress concentration on the corner portions may be prevented. Accordingly, it is possible to reduce the likelihood of the occurrence of peeling of the bonding member 4 from the mounting surface 5a.

By the way, in a power conversion system, a capacitor is disposed on a side portion of a semiconductor device. Therefore, in the semiconductor device, a main terminal may be disposed on the side portion of the semiconductor device. The main terminal of the semiconductor device and a bus bar of the capacitor disposed on the side portion of the semiconductor device are electrically joined by laser welding or screwing. This case imposes a limit on the miniaturization of the semiconductor device. In addition, there is a limit on the reduction of the inductance generated between the semiconductor device and the capacitor.

Therefore, the semiconductor device 2 includes the semiconductor chips 10a and 10b, the insulated circuit substrate 20 including the metal plate 23, the insulating layer 21 disposed on the upper surface of the metal plate 23 in a state where the ground region 24a included in the upper surface of the ground metal plate 24 included in the metal plate 23 is exposed, and the conductive circuit pattern plate 22 on which the semiconductor chips 10a and 10b are disposed, and the conductive ground terminal 28 conductively connected to the ground region 24a of the ground metal plate 24 and having the upper end portion located above the insulated circuit substrate 20. In addition, the semiconductor device 2 includes the sealing member 40 that seals the semiconductor chips 10a and 10b, the insulated circuit substrate 20, and the ground terminal 28 and that includes the opening 42 in the sealing upper surface that exposes the upper end portion of the ground terminal 28 above the insulated circuit substrate 20. The semiconductor device 2 further includes the conductive first main terminal 25, second main terminal 26, and third main terminal 27 that are provided on the upper surface of the conductive circuit pattern plate 22 and each have an upper end portion. The sealing member 40 further seals the first main terminal 25, the second main terminal 26, and the third main terminal 27. The upper end portions of the first main terminal 25, the second main terminal 26, and the third main terminal 27 are exposed from the sealing upper surface 41a. As described above, in the semiconductor device 2, the first main terminal 25, the second main terminal 26, the third main terminal 27, and the ground terminal 28 extend vertically upward from the semiconductor device 2. Therefore, the size of the semiconductor device 2 itself may be reduced. Further, the bus bars 7a and 7b of the capacitor 7 may be connected to the first main terminal 25 and the second main terminal 26 of the semiconductor device 2 from above, and the inductance may be reduced.

In a semiconductor device, for example, a ground terminal is connected to a cooling module. On the other hand, in the semiconductor device 2, the ground terminal 28 also extends vertically upward from the semiconductor device 2, as with the first main terminal 25, the second main terminal 26, and the third main terminal 27. As a result, the ground potential of the semiconductor device 2 is stabilized, compared to the case where the ground terminal is connected to the cooling module.

### SECOND EMBODIMENT

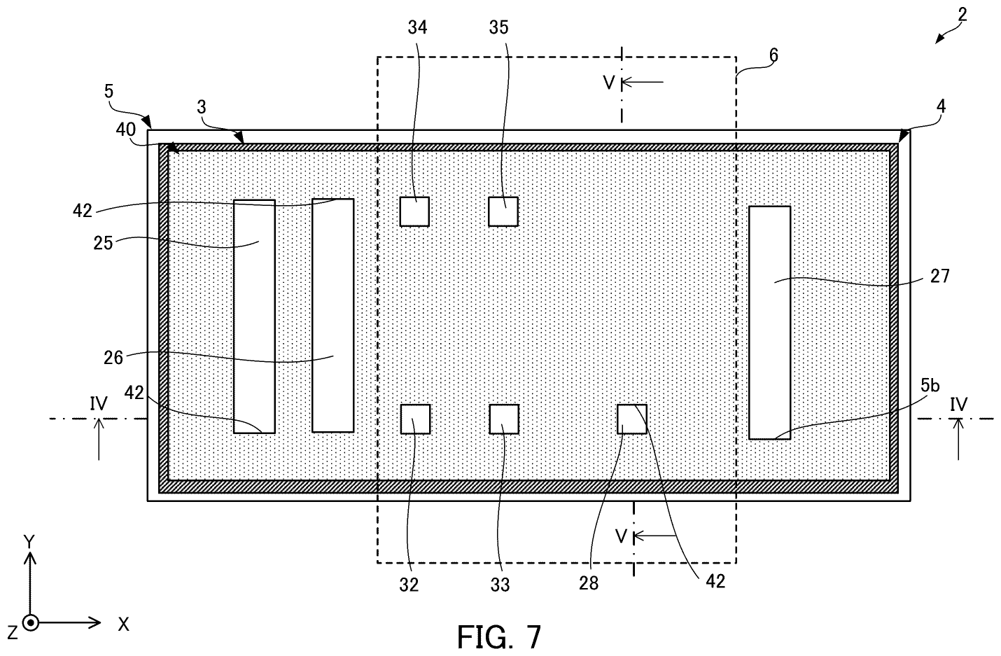

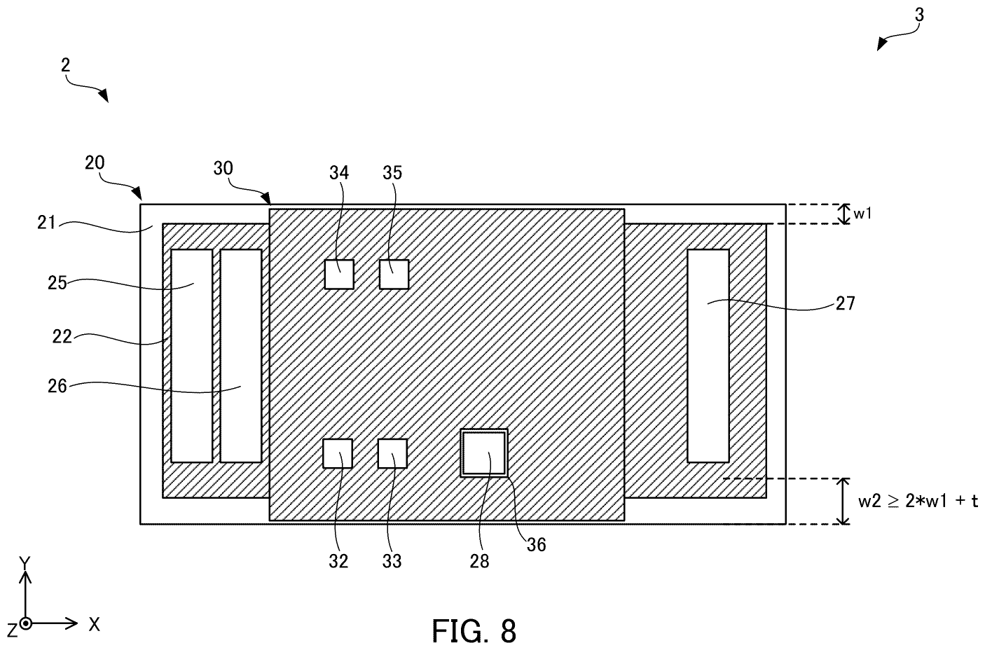

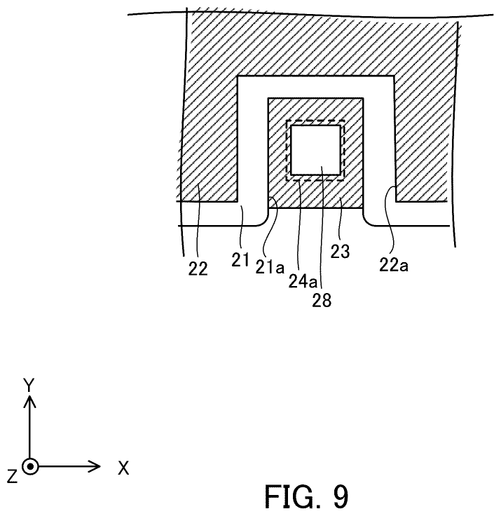

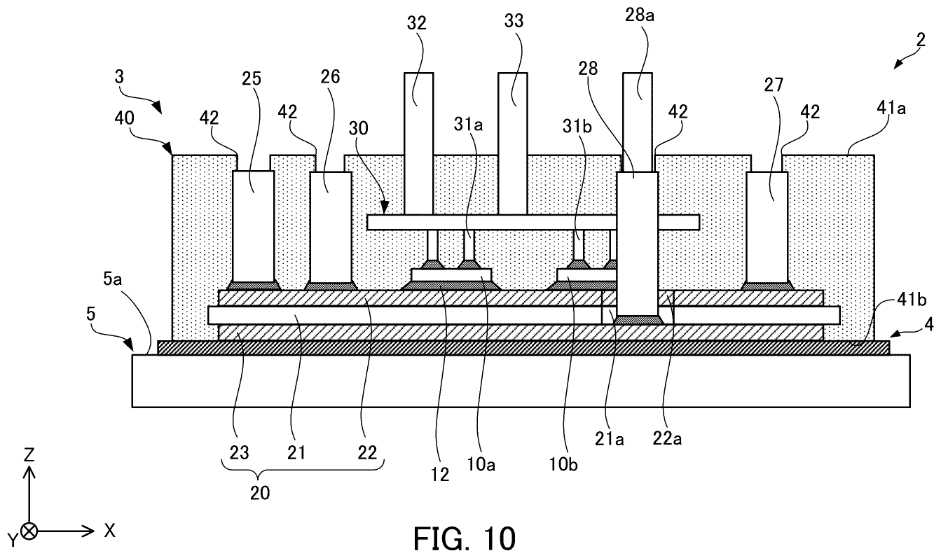

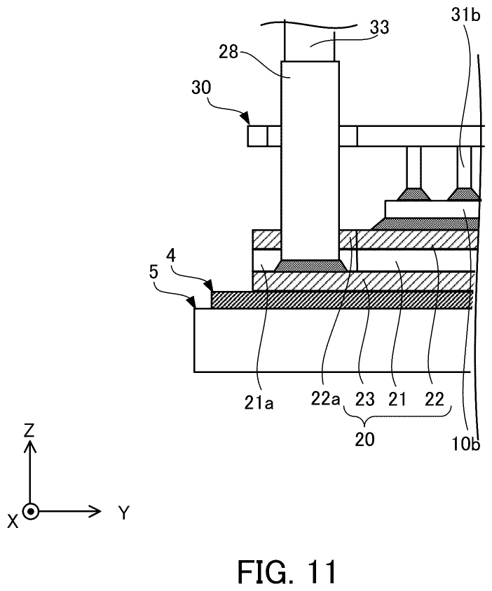

A semiconductor device of a second embodiment differs from that of the first embodiment in the arrangement position of the ground terminal. The semiconductor device in this case will be described with reference to FIGS. 7 to 11. FIG. 7 is a plan view of the semiconductor device according to the second embodiment. FIG. 8 is a plan view of the semiconductor device (excluding a sealing member) according to the second embodiment. FIG. 9 is a plan view of an insulated circuit substrate according to the second embodiment. FIG. 10 is a first sectional view of the semiconductor device according to the second embodiment. FIG. 11 is a second sectional view of the semiconductor device (excluding the sealing member) according to the second embodiment.

More specifically, FIG. 8 is a plan view of a semiconductor module 3 (semiconductor device 2) with a sealing member 40 removed from FIG. 7. FIG. 9 is an enlarged view illustrating a ground region 24a and its periphery in an insulated circuit substrate 20 of FIG. 8. FIG. 10 is a sectional view taken along the dot-dashed line IV-IV of FIG. 7. FIG. 11 is a sectional view taken along the dot-dashed line V-V of FIG. 7. In this connection, in FIG. 11, the sealing member 40 is not illustrated. The semiconductor device 2 of the second embodiment has the same configuration as the semiconductor device 2 of the first embodiment except for the arrangement position of the ground terminal 28. Hereinafter, the description of the same configuration as that of the semiconductor device 2 of the first embodiment will be simplified or omitted.

The semiconductor device 2 of the second embodiment also includes the semiconductor module 3, a cooling module 5 on which the semiconductor module 3 is disposed via a bonding member 4, and a first printed board 6 attached to the semiconductor module 3. Note that the arrangement position of the first printed board 6 with respect to the semiconductor module 3 is indicated by a broken line in FIG. 7, and is not indicated in other drawings. Note that the semiconductor module 3 may include other needed components in addition to these components.

The semiconductor module 3 includes semiconductor chips 10a and 10b, an insulated circuit substrate 20, a second printed board 30, a first main terminal 25, a second main terminal 26, a third main terminal 27, and a ground terminal 28, and also includes the sealing member 40 that seals these components.

The insulated circuit substrate 20 includes an insulating layer 21, a conductive circuit pattern plate 22, and a metal plate 23. The insulating layer 21 of the second embodiment is made of resin containing a filler. Examples of the resin include an epoxy resin. Examples of the filler include boron nitride.

In the insulating layer 21, a ground opening 21a is formed at a position corresponding to a ground region 24a where the ground terminal 28 is disposed. In addition, it is preferable that the outer corners of the ground opening 21a formed in the insulating layer 21 are R-chamfered. The conductive circuit pattern plate 22 also has a ground opening 22a at a position corresponding to the ground region 24a where the ground terminal 28 is disposed. Therefore, in the metal plate 23, the ground region 24a is exposed in the ground openings 21a and 22a.

The ground terminal 28 is disposed in the ground region 24a of the metal plate 23, which are exposed in the ground openings 21a and 22a, in the insulated circuit substrate 20. At this time, the ground terminal 28 is conductively connected to the metal plate 23 via, for example, the above-described solder.

The insulating layer 21 of the insulated circuit substrate 20 of the second embodiment is not made of a ceramic material as in the first embodiment, but is made of an epoxy resin containing a boron nitride filler. Therefore, the ground opening 21a may be formed at a side of the insulating layer 21. Further, since the ground opening 21a of the insulating layer 21 of the second embodiment has R-chamfered corners, it is possible to reduce the likelihood of the occurrence of cracking even when the insulating layer 21 expands and contracts.

In the semiconductor device 2 of the second embodiment, as in the first embodiment, the first main terminal 25, the second main terminal 26, the third main terminal 27, and the ground terminal 28 extend vertically upward from the semiconductor device 2. Therefore, the inductance in the semiconductor device 2 may be reduced, and the ground potential of the semiconductor device 2 is stabilized.

In addition, in the semiconductor device 2 of the second embodiment, the ground terminal 28 is disposed inward in the +Y direction in plan view, compared to the case of the first embodiment. Accordingly, the first control terminal 32, the first sense terminal 33, the second control terminal 34, and the second sense terminal 35 are also disposed inward with respect to the insulated circuit substrate 20, and thus the semiconductor device 2 may be more miniaturized than in the first embodiment.

According to the disclosed techniques, it is possible to reduce inductance.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
an insulated circuit substrate, including:
a metal plate including a ground region on an upper surface thereof,
an insulating layer disposed on the upper surface of the metal plate, with the ground region exposed therefrom, and
a conductive circuit pattern plate on which the semiconductor chip is mounted;
a ground wiring member conductively connected to the ground region of the metal plate, the ground wiring member being conductive and including an upper end portion located above the insulated circuit substrate; and
a sealing member sealing the semiconductor chip, the insulated circuit substrate, and the ground wiring member, the sealing member having a sealing upper surface and including an opening formed therein to expose therethrough the upper end portion of the ground wiring member above the insulated circuit substrate.

2. The semiconductor device according to claim 1, wherein
the ground wiring member has a first flat surface at the upper end portion thereof, and
at least part of the first flat surface is exposed in the opening.

3. The semiconductor device according to claim 1, wherein
the upper end portion of the ground wiring member extends upward from the sealing upper surface of the sealing member, and
the semiconductor device further includes a first printed board attached to the upper end portion of the ground wiring member.

4. The semiconductor device according to claim 1, further comprising
a main terminal wiring member provided on an upper surface of the conductive circuit pattern plate, the main terminal wiring member being conductive and including an upper end portion thereof,
wherein the sealing member further seals the main terminal wiring member in such a manner that the upper end portion of the main terminal wiring member is exposed from the sealing upper surface.

5. The semiconductor device according to claim 4, wherein the main terminal wiring member is disposed at one end of the insulated circuit substrate in a plan view of the semiconductor device.

6. The semiconductor device according to claim 5, wherein the ground wiring member is disposed at another end of the insulated circuit substrate, opposite to the one end at which the main terminal wiring member is disposed, in the plan view.

7. The semiconductor device according to claim 1, wherein
the metal plate includes a portion projecting outward from the insulating layer in a plan view of the semiconductor device, and
the ground region is formed on the upper surface of the metal plate in said portion.

8. The semiconductor device according to claim 1, wherein
the insulated circuit substrate has a rectangular shape in a plan view of the semiconductor device, and
each of the insulating layer and the conductive circuit pattern plate has an opening through which the ground region is exposed.

9. The semiconductor device according to claim 8, wherein the insulating layer is made of resin containing a filler.

10. The semiconductor device according to claim 9, wherein the filler is boron nitride.

11. The semiconductor device according to claim 9, wherein the resin is an epoxy resin.
